(19) United States
(12) Patent Application Publication
(10) Pub. No.: US 2010/0229914 A1
(43) Pub. Date: Sep. 16, 2010

(54) Solar cells with shunt resistance

(75) Inventors: Paul M. Adriani, Palo Alto, CA (US); Shandor Daroczi, Santa Clara, CA (US); Damoder Reddy, Los Gatos, CA (US)

Correspondence Address: NOLD INTELLECTUAL PROPERTY LAW, 101 California Street, Suite 2450, San Francisco, CA, 94111, US

(73) Assignee: Solexant Corp., San Jose, CA (US)

(21) Appl. No.: 12/658,334

(22) Filed: Feb. 9, 2010

Related U.S. Application Data
(63) Continuation-in-part of application No. 12/455,326, filed on Jun. 1, 2009.
(60) Provisional application No. 61/130,926, filed on Jun. 4, 2008.
(60) Provisional application No. 61/131,179, filed on Jun. 7, 2008.

(51) Int. Cl. H01L 31/042; H01L 31/00

(52) U.S. Cl. 136/244; 136/252

(57) ABSTRACT

Photovoltaic devices are disclosed that have built in shunt resistance. The devices comprise shunt isolation lines in the electrodes such that shunts will not degrade the efficiency of each individual unit cell. The device is easy to manufacture and the invention is suitable for use with most photovoltaic device architectures.

### CROSS REFERENCE TO RELATED APPLICATIONS

This application claims priority to U.S. Ser. No. 12/455,326, filed Jun. 1, 2009, which claims priority to U.S. Provisional Patent Application Ser. No. 61/130,926 filed Jun. 4, 2008 and 61/131,179, filed Jun. 7, 2008, the contents of all are incorporated herein by reference.

### BACKGROUND OF THE INVENTION

Solar cells are one of the most promising energy sources available. However, further improvement needs to be made in their efficiency to make them more economically competitive with other energy sources. The invention presented herein provides solar cell technology that dramatically, surprisingly and unexpectedly improves solar cell efficiency.

A shunt is a local increase in the dark forward current of a cell. This increase can be caused by material defects or it can be process induced. Material induced shunts can occur due to a high density of dislocations, voids or impurities as well as metal-decorated small angle grain boundaries, grow-in macroscopic SiₓN_{y} inclusions and inversion layers crossing the wafer. Shunts can be created during processing by residues of the emitter at the cell edge, by cracks and holes, by scratches and by aluminum particles at the cell surface. Schottky type shunts can also occur below grid lines.

FIG. 1 shows a cross section view of a prior art monolithic thin-film photovoltaic device 100 having a front electrode layer 108, beneath that a window layer 107, beneath that an absorber layer 106, beneath that a back electrode layer 105 resting on a substrate 102. Cells 115, 125 and 135 are separated by back electrode isolation lines 110 and 120. Front electrode isolation line 113 cuts through the front electrode and electrically insulates the front electrode and separates cells 115 and 125. The window/absorber isolation line 112 cuts through the window layer and the absorber layer and provides an electrical path from the front electrode to the back contact of an adjacent cell. Normal current flow without a shunt is shown by arrow 150. The offsets between the isolation lines 110 and 113 allows current to flow between cells.

FIG. 2 shows a top view of a prior art monolithic device 200 having multiple cells 215, 225 and 235 similar to those shown in FIG. 1, connected in series. The top layers of this device are transparent and one can see the absorber layer. In this device each cell 215, 225 and 235 is approximately 10 mm by 725 mm. Isolation lines 210, 220 and 230 separate cells 215, 225 and 235.

FIG. 2A shows a top view of a section of a prior art monolithic device 200A comprising a substrate 203A and a back electrode layer 204A. Isolation lines 210A, 220A and 230A separate cells 215A, 225A and 235A.

FIG. 3 shows an image of the top of a section of a prior art monolithic device. Isolation lines 310, 320 and 330 separate cells 315, 325 and 335. Arrow 350 shows the direction of normal current flow across the device when working properly. The photocurrent generated by each individual cell flows from one end of the device to the other. The device voltage is simply the sum of the voltages from the series connected individual cells.

FIG. 3A shows a cross section of a device, and a shunt 360 short circuits the front electrode and the back electrode in cell 315. Cells 315, 325 and 335 are separated by back electrode isolation lines 310 and 320 which cut through the back electrode. Shunt 360 disrupts some of the current flow within the cell, and thereby reduces the overall voltage of the device. Because of shunt 360 in cell 315 normal current flow ceases in that cell. In this example neighboring cell 325 still has normal current flow 350. A substantial area of the affected cell has its current diverted to the shunt rather than the normal current flow. Thus there is a reduction in the overall voltage of the device due to that cell.

The efficiency of a device is affected because shunts reduce the Fill Factor (FF) and the Open Circuit Voltage (Voc). This effect becomes more dominant under low light conditions. A low shunt resistance can lead to hot-spots in reverse biased cells, especially when the power dissipation occurs in a small area. Open-circuit voltage is the potential difference between the cathode and anode of a cell when there is no current flowing through the cell. Short-circuit current is the current that flows when the terminals are shorted together. Open-circuit voltage (VOC) and short-circuit current (JSC), where J is current, are determined as VOC=V at J=0 and JSC=J at V=0, respectively. The fill factor (FF) is the ratio of power at the maximum power point to the product of VOC and JSC.

FF=Pm/(VOC×JSC).

The cell efficiency (η) of a device is the ratio of maximum power (Pm) per unit area, the output electricity over PS the incident illumination power per unit area: η=Pm/PS=(VOC×JSC×FF)/PS. Thus it can be seen that the efficiency of a solar cell is reduced because of the shunting present in the cell.

There remains a need in the photovoltaic device art for a device having improved shunt resistance. The present invention discloses a photovoltaic device that has built in shunt resistance.

### SUMMARY OF THE INVENTION

In one embodiment the invention discloses a photovoltaic device comprising a plurality of cells, wherein each cell comprises a front electrode and/or a back electrode, and at least two cells are separated by a back electrode isolation line and/or a front electrode isolation line, and at least one cell further comprises a first shunt isolation line, wherein the first shunt isolation line is in the back electrode and/or the front electrode. In another embodiment the first shunt isolation line is substantially perpendicular to the back electrode isolation line. In another embodiment the first shunt isolation line divides at least two cells partially or wholly. In another embodiment the first shunt isolation line comprises a series of shunt isolation lines. In another embodiment a second shunt isolation line is substantially perpendicular to the first shunt isolation line. In another embodiment the first shunt isolation line is substantially non-orthogonal to the back electrode isolation line. In another embodiment the first shunt isolation line is substantially parallel to the back electrode isolation line. In another embodiment the first shunt isolation line is located underneath the front electrode isolation line. In another embodiment the first shunt isolation line comprises a series of first shunt isolation lines. In another embodiment a second shunt isolation line is located in the back electrode. In another embodiment the first shunt isolation line is substantially parallel to the second shunt isolation line. In another embodiment the invention discloses a plurality of discrete cells connected in electrical series, wherein each cell comprises a front electrode and a back electrode, and at least one discrete cell comprises a first shunt isolation line, wherein the first shunt isolation line is in the back electrode and/or the front electrode. In another embodiment each cell comprises a first edge, wherein the first shunt isolation line is substantially parallel to the first edge. In another embodiment the first shunt isolation line divides a cell partially or wholly. In another embodiment the first shunt isolation line is in the back electrode. In another embodiment the first shunt isolation line comprises a series of shunt isolation lines. In another embodiment a second shunt isolation line is substantially perpendicular to the first shunt isolation line. In another embodiment the first shunt isolation line is substantially parallel to a second shunt isolation line. In another embodiment, each cell comprises a first edge, and the first shunt isolation line is substantially non-orthogonal to the first edge. In another embodiment the invention discloses a cell material and/or a roll of cell material comprising a substrate, a back electrode, an absorber layer, and a front electrode, and at least one cell comprises a shunt isolation line, wherein the shunt isolation line is in the back electrode and/or the front electrode. In another embodiment there is disclosed a photovoltaic device comprising a shunt isolation line wherein the cell open circuit voltage is greater compared to a similar cell open circuit voltage without the shunt isolation line.

### BRIEF DESCRIPTION OF THE DRAWINGS

FIG. 1 shows a cross section of a series-connected prior art thin-film monolithic cell showing isolation lines.

FIG. 2 shows a top view of a prior art monolithic device showing isolation lines and unit cells.

FIG. 2A shows a projection view of a prior art monolithic device showing isolation lines and unit cells.

FIG. 3 shows a section of a prior art monolithic device showing current flow when a shunt is present.

FIG. 3A shows a cross section of a prior art monolithic device showing the location of a shunt.

FIG. 4 shows a monolithic device having shunt isolation lines according to one embodiment of the invention.

FIG. 5 shows a section of a monolithic device having shunt isolation lines according to one embodiment of the invention.

FIG. 6 shows one embodiment of the invention where back electrode shunt isolation lines divide unit cells.

FIG. 7 shows various embodiments of shunt isolation lines in a device of the present invention.

FIG. 8 shows various embodiments of shunt isolation lines in a device of the present invention.

FIG. 9 shows a cross section of a monolithic device having two shunt isolation lines in the back electrode.

FIG. 10 shows various embodiments of shunt isolation lines in devices of the present invention.

FIG. 11 shows various embodiments of shunt isolation lines in devices of the present invention.

FIG. 12 shows various embodiments of shunt isolation lines in devices of the present invention.

FIG. 13 shows front electrode shunt isolation lines in devices of the present invention.

FIGS. 14A-E show various embodiments of shunt isolation lines in devices of the present invention.

FIG. 15 shows a discrete cell having shunt isolation lines in the back electrode.

FIG. 16 shows a discrete cell having shunt isolation lines in the top layers.

FIG. 17 shows a discrete cell with shunt isolation lines in the back contact and the back electrode and rest of the top layers.

FIG. 18 shows a device having a plurality of discrete cells connected in series with shunt isolation lines.

FIG. 19 shows a device having a plurality of discrete cells connected in series with isolation lines.

FIG. 20 shows a discrete cell having shunt isolation lines and portions of the top layers removed.

FIG. 21 shows a device having a plurality of discrete cells connected in series with isolation lines.

FIG. 22 shows a device having a plurality of discrete cells having isolation lines connected in series.

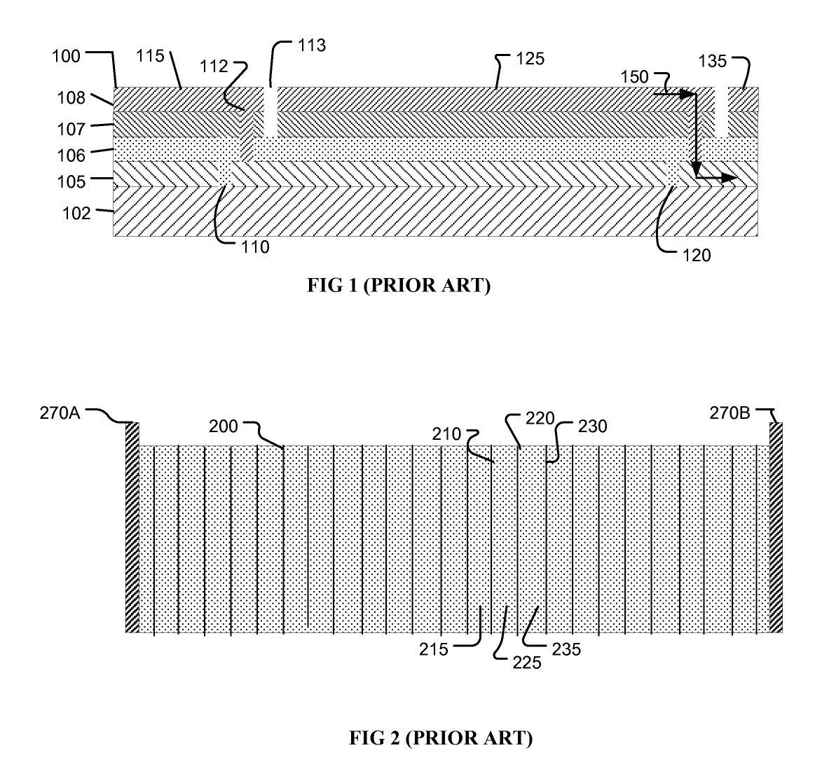

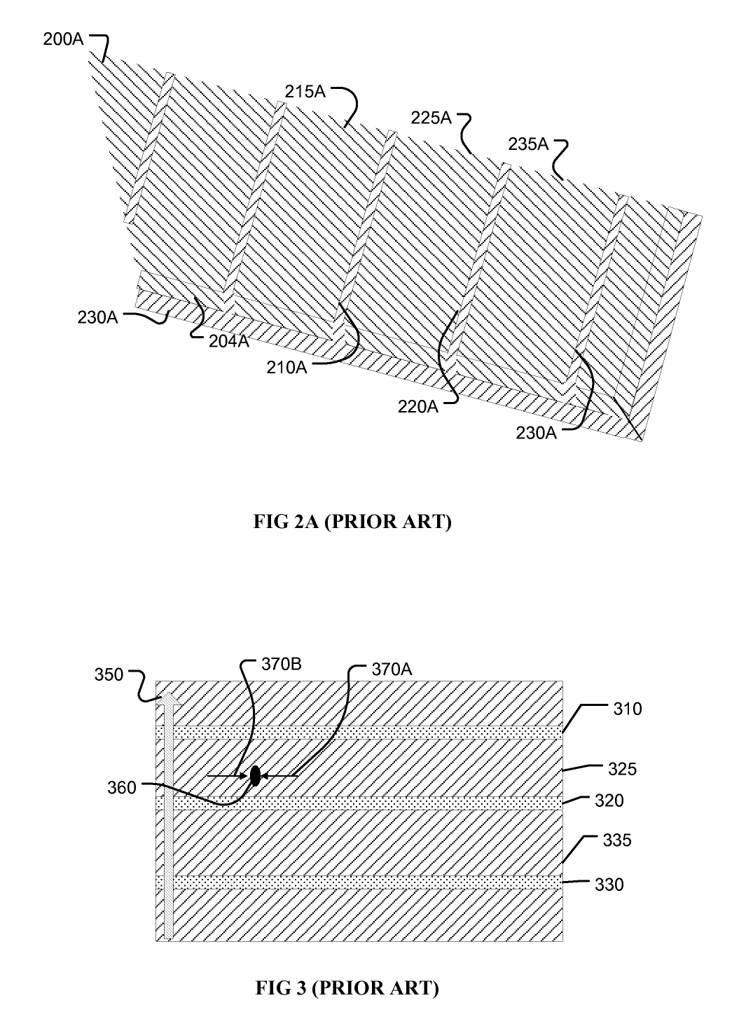

### DETAILED DESCRIPTION OF THE EMBODIMENTS

Reference will now be made in detail to some specific embodiments of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In this specification and the appended claims, the singular forms “a,” “an,” and “the” include plural reference unless the context clearly dictates otherwise. Unless defined otherwise, all technical and scientific terms used herein have the same meaning as commonly understood to one of ordinary skill in the art to which this invention belongs.

The present invention improves device efficiency by reducing the effects of shunts on voltage of any individual cell by building into the device shunt isolation lines.

The invention described herein is suitable for any solar cell device including those known monolithic and discrete devices including both substrate and superstrate architectures.

By “photovoltaic device” as used herein it is meant a multilayered structure where in a working environment is capable of converting light into electricity. The device may have any structure necessary to practically utilize the device such as leads, connections, etc.

Preferably cells in accordance with the present invention have the following layers as a minimum: a back electrode, a PN junction (such as an absorber/window combination) and a front electrode (transparent conductor layer or transparent conducting electrode). Preferably the back electrode is conductive and more preferred is a metal electrode.

Monolithic photovoltaic devices are those devices where at least two cells share a common layer of material, such as a substrate, absorber layer, window layer, and/or front or back electrode and adjacent photovoltaic cells are separated by at least one isolation line that cut through the back electrode and/or the front electrode. Discrete photovoltaic devices are those devices having two cells that do not share a common layer of material. Cells in accordance with this invention are not restricted by shape.

In one embodiment of the present invention each photovoltaic cell preferably comprises a substrate, an electrode disposed on both (opposite) sides of the substrate, a barrier layer, an absorber layer, a window layer and a transparent conducting oxide electrode layer. Adjacent photovoltaic cells are separated by isolation lines that cut through the bottom electrode near an interconnect via at an edge of a cell. The bottom electrode of one cell and the back electrode of its adjacent cell are not in electrical contact except for the serial interconnect via. Examples of these devices are given in commonly assigned and copending US Publication No. 20090301543 A1, published Dec. 10, 2009 the contents of which are incorporated herein by reference in its entirety.

By “isolation line” it is meant an area separating a first area comprising one or more materials and/or layers from another area comprising one or more materials and/or layers. “Back electrode isolation lines” and “front electrode isolation lines” as used in some embodiments herein are those isolations lines that cut through either the back electrode and/or the front electrode and divide monolithic devices into unit cells. Also, “back electrode isolation lines” and “front electrode isolation lines may describe isolation lines used to electrically isolate back electrodes of adjacent discrete cells when connected in series. Typically these isolation lines extend substantially perpendicular to the current flow in the back electrode. They may extend non-orthogonally as well. The term “line” as used herein is not restricted to a “straight” or substantially straight line.

The invention contemplates that a “shunt isolation line” cuts through an electrode and/or other layers in monolithic and discrete cells. Shunt isolation lines in accordance with this invention may partially divide, substantially divide or wholly divide a cell such that voltage loss due to a shunt in the cell will be minimized. Multiple shunt isolation lines may be present in a single cell which are independently the same or different which may partially divide, substantially divide and/or wholly divide a cell. Shunt isolation lines according to the present invention are not restricted by shape or size. They may comprise circles, squares and/or complex shapes. There may be one, two, three or any number of the same or similarly shaped shunt isolation lines or patterns disposed asymmetrically or symetrically on a device, such as in a straight line. In some embodiments shunt isolation lines intersect at various angles and thus are sometimes called shunt isolation patterns. Two or more different shunt isolation lines may intersect one another. One single shunt isolation line may intersect itself. Shunt isolation lines may be filled or unfilled with any suitable material, especially preferred is that which imparts barrier properties. Shunt isolation lines described herein are advantageous in cells and/or devices having substrate, superstrate, single junction, multi junction, monolithic and/or discrete architectures.

Shunt isolation lines according to the present invention are used in either or both electrodes of a device, but preferably they are used in the electrode that has the greater conductivity of the two. Examples used herein depict the back electrode as the electrode with the greater conductivity. It is understood that the shunt isolation lines as described herein may be in the back electrode layer and/or the front electrode (TCO) layer. The shunt isolation lines may have varying widths. They may be about 1 μm up to any size. Preferably they are about 30-50 μm.

Non-limiting examples of materials suitable for photovoltaic cell layers disclosed herein may be found in Durstock, M. et al. “Materials for photovoltaics: symposium held Nov. 29-Dec. 2, 2004, Boston, Mass., USA: Symposium proceedings/Materials Research Society v. 836 (2005), the contents of which are incorporated herein by reference. The invention as described herein is also suitable for tandem photovoltaic cells. Suitable architecture for tandem devices useful with this invention are described in “Preparation and Characterization of Monolithic HgCdTe/CdTe Tandem Cells” Mater. Res. Soc. Symp. Proc. Vol. 836, p. 265-270 (2008), the contents of which are incorporated herein by reference. The invention contemplates that each photovoltaic cell used in a photovoltaic device does not need to be the same. They may be varied by layer structure, materials, shape, or other parameter.

The absorber layer used in conjunction with photovoltaic cells of the present invention comprises a film comprising a semiconductor compound capable of photoelectric conversion chosen from the group consisting of Group I-VI, II-VI, III-V and IV-VI compounds and Group IV semiconductors and organic semiconductors. Deposition methods for the CdTe include close-spaced sublimation (CSS) (preferred), spray deposition (SD), screen printing and electrodeposition. Other absorber materials include I-III-VI compounds such as CIGS. CIGS is CuInₓGa₁₋ₓSe, where 0≦x<1 and included herein is the family of materials known in the art as CIGS including CIS, CISe, CIGSe, CIGSSe. Organic semiconductors suitable for use in the present invention include poly(3-hexylthiophene), or poly(3-octylthiophene) and others known in the art, see for example Drndic, M. et al. U.S. Published Patent Application No. 20070102694 filed Feb. 6, 2006 the contents of which are incorporated herein by reference. The absorber layer preferably has a thickness of between about 1-10 microns.

Suitable window materials are CdS, CdSe, ZnS, ZnSe and oxysulfides. Currently CdS forms the best heterojunction with CdTe and is thus preferred. The window layer may have a thickness of 50-200 nm. The CdS may be deposited using a PVD process such as sputtering or evaporation.

Substrates used in accordance with the instant invention may comprise an insulating or conductive material. The substrate can be a conductive opaque metal foil such as stainless steel, aluminum or copper, a flexible transparent polymer film (such as polyimide, a polyamide, a polyethersulfone, a polyetherimide, a polyethylene naphthalate, a polyester, etc.) or a rigid transparent glass (borosilicate or soda lime). Preferably the substrate is flexible. The thickness of the substrate can be any suitable size depending on desired end use but it is preferably 25-250 microns for flexible metal foils, 10-100 microns for flexible polymer films or 1-5 mm for glass.

Suitable materials for the metal electrodes of the present invention include Mo, Ti, Ni, Al, Nb, W, Cr, and Cu as non-limiting examples. Preferred is Mo, Ti or Ni. The metal electrode layer thickness can range from 50 nm to 2,000 nm, more preferred is 250-2000 nm. The metal layer can be deposited by physical vapor deposition techniques known in the art. The invention does not limit an electrode layer to be positioned directly on top on the substrate surface. The transparent conducting electrode are usually n-type materials with good conductivity and high transparency in the visible spectrum and may comprise a material chosen from the group consisting of ZnO, ITO, SnO₂, Cd₂SnO₄, In₂O₃ or Zn₂SnO₄. Two different transparent conducting electrode layers may be used in combination if desired and thus take advantage of differing properties of two different materials.

The invention contemplates that various interface layers may be present in the photovoltaic cells to match adjacent layers crystal structure, microstructure, lattice constant, electron affinity/work function, thermal expansion coefficient, diffusion coefficient, chemical affinity and mobility, mechanical adhesion and mobility, interface stress, defect and interface states, surface recombination centers, etc. Examples of materials suitable for an interface layer between an electrode layer and the absorber layer include those materials and layers disclosed in commonly assigned and copending U.S. Ser. No. 12/381,637 filed 13 Mar. 2009, the contents of which is incorporated herein by reference. In some embodiments it may be useful to include interface layers as taught in commonly assigned and copending U.S. Ser. No. 12/383,532, filed 24 Mar. 2009, the contents of which are incorporated herein by reference, especially between the absorber layer and the window layer. Also included are those layers that create an ohmic contact to the absorber layer disclosed in commonly assigned and copending U.S. Ser. No. not yet assigned filed 28 Jan. 2010 entitled “Back Contact for Thin Film Solar Cells”, the contents of which is incorporated herein by reference.

Substrate monolithic photovoltaic devices suitable for use in this invention may be made as follows. Onto a substrate is deposited a conducting metal layer to function as a for a back contact electrode. The metal layer is laser scribed according to embodiments of this invention to create a shunt isolation line for shunt resistance. It is preferable to minimize the distance between the back electrode shunt isolation lines to minimize the affected shunted area. This will help maximize the effective current producing area. Interface layers comprising materials such as ZnTe can be deposited at a 50-500 nm thickness on the back electrode layer before depositing the absorber layer. The absorber layer can be deposited by sputtering or other physical vapor deposition (PVD) methods known in the art for this purpose, such as close space sublimation (CSS), vapor transport deposition (VTD), evaporation, close-space vapor transport (CSVT) or by chemical vapor deposition (CVD) methods. A window layer comprising CdS may be deposited on top of the absorber layer. A transparent conducting oxide layer is then deposited and subsequently scribed in a direction substantially perpendicular to the back contact isolation line to isolate adjacent cells. As used herein “deposit” or “depositing” includes the steps of forming a layer, including but are not limited to those step or steps for forming, reacting, masking/etching and/or scribing a layer which includes physical vapor deposition (PVD), chemical vapor deposition (CVD), evaporation and sublimation. Suitable techniques for forming the layers disclosed herein include the roll to roll continuous process disclosed in commonly assigned and copending U.S. Ser. No. 12/380,638, filed 2 Mar. 2009, the contents of which are incorporated herein by reference. By “scribe” it is meant a portion removed or cut away, when used as a noun usually by laser patterning. Scribing techniques suitable for use with the present invention include but are not limited to mechanical or laser techniques. This includes shadow masking and/or contact mask and etch.

### EXAMPLE 1

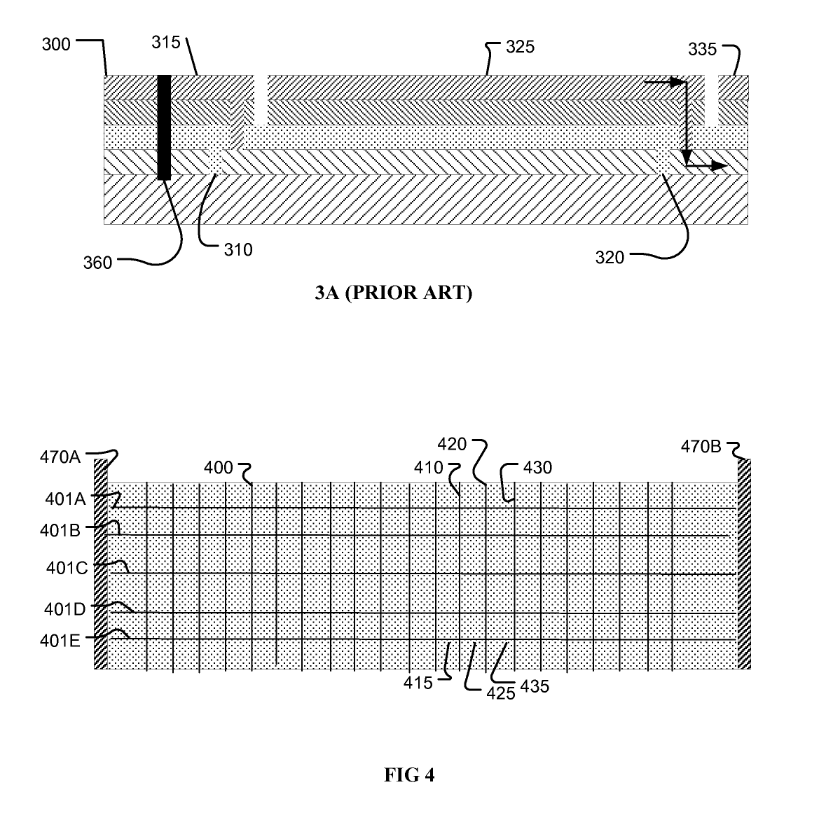

FIG. 4 shows a photovoltaic device 400 according to one embodiment of the present invention having shunt isolation lines 401A, 401B, 401C, 401D and 401E designed to limit the shunt affected area of a solar cell device. Back electrode isolation lines 410, 420 and 430 separate cells 415, 425 and 435. Current flow is between bus bar 470A and 470b. Shunt isolation lines 401A, 401B, 401C, 401D and 401E may be scribed into the back electrode layer of the device. The shunt isolation lines in this embodiment run perpendicular and/or substantially perpendicular to the isolation lines 410, 420 and 430. The distance between the shunt isolation lines 401A, 401B, 401C, 401D and 401E in this embodiment may be varied depending taking into account such factors as cell length, width, etc.

### EXAMPLE 2

FIG. 5 shows one embodiment of the present invention having shunt isolation lines 501A, 501B, 501C and 501D in the back electrode of a device. The back electrode isolation lines 510, 520 and 530 separate cells 515, 525 and 535. Arrow 550 shows the direction of current flow across the device when working properly. When there is a shunt 560 in cell 525 normal current flow ceases and current flow path is according to the arrows 570A and 570B. However, in this embodiment having shunt isolation lines 501A, 501B, 501C and 501D in the back electrode of a device the current flow paths 570A and 570B are restricted to the sub divided portion. Comparing FIG. 3 flow paths 370A and 370B to 570A and 570B one can see that the current flow path is limited in the device of FIG. 5. Thus there is negligible contribution to the entire series voltage of the device contributed by that cell because the voltage loss is limited to the area between shunt isolation lines in each cell.

### EXAMPLE 3

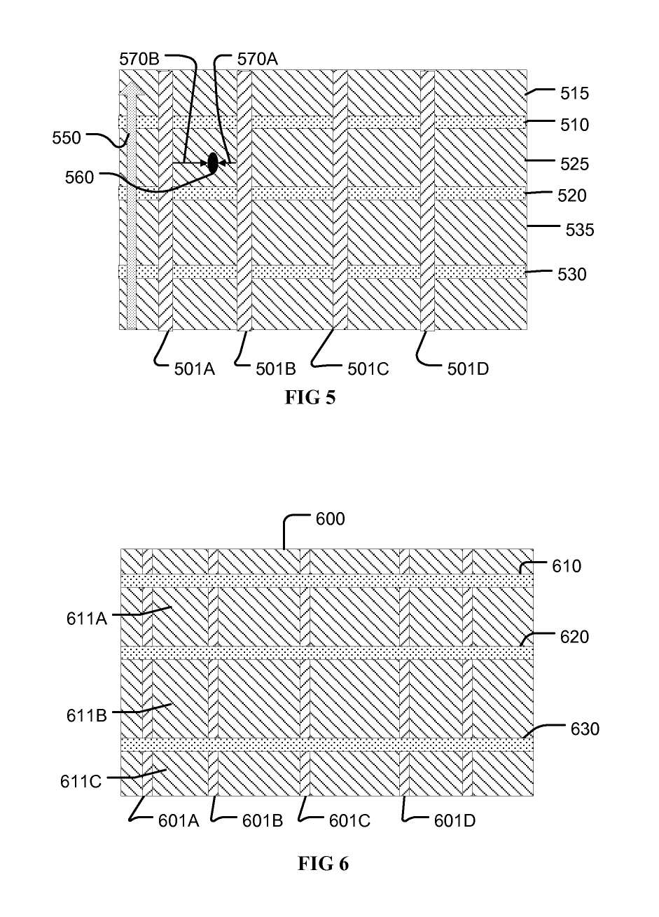

FIG. 6 shows a top view of a section of the back electrode layer of a device 600 according to one embodiment of the present invention. Isolation lines 610, 620 and 630 separate individual cells of the device and shunt isolation lines 601A, 601B, 601C and 601D divide the cells into sub-cells 611A, 611B and 611C. It is preferred that the shunt isolation lines 601A, 601B, 601C and 601D fully cut through the back electrode layer for isolation.

### EXAMPLE 4

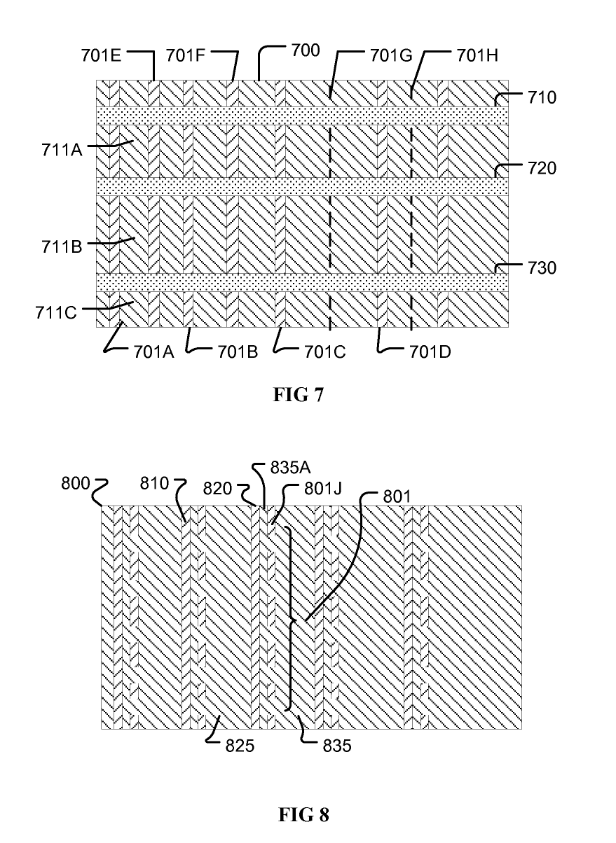

FIG. 7 shows a top view of a section of the back electrode layer of a device 700 according to one embodiment of the present invention. Isolation lines 710, 720 and 730 separate individual cells of the device and shunt isolation lines 701A, 701B, 701C and 701D divide the cells into sub-cells 711A, 711B and 711C. Shunt isolation lines 701E and 701F allow for further division of a cell. The spacing between shunt isolation lines 701E and 701F as well as other shunt isolation lines according to this invention is variable. Shunt isolation lines 701E and 701F may have any width. Shunt isolation lines 701G and/or 701H depict multiple lines or a “series” of back electrode shunt isolation lines. A “series” means a plurality of shunt isolation lines arranged in a substantially symmetrical pattern, for example a straight line. The spacing between each individual shunt isolation line in the series 701G and 701H may be the same or different.

### EXAMPLE 5

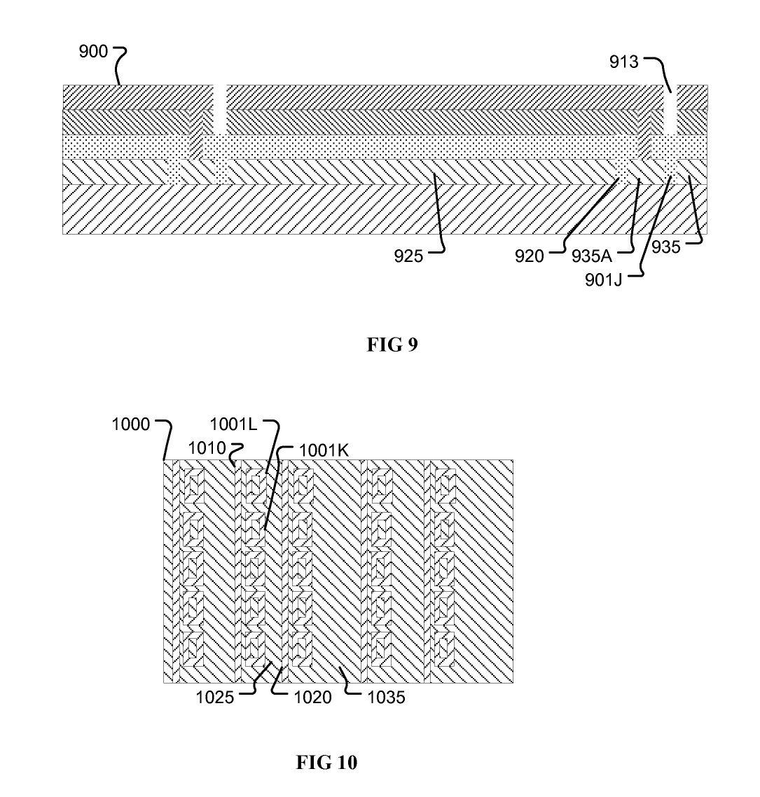

In another embodiment of the invention shown in FIG. 8 there is a top view of a portion of a device showing the back electrode layer. Isolation lines 810 and 820 separate the cells 825 and 835 through the back electrode layer. Shunt isolation line 801J is placed near isolation line 820 separated by back electrode area 835A. The distance between 801J and 820 is preferably equal to or greater than the width of window/absorber layer isolation line. Shown is a shunt isolation line series 801 of individual shunt isolation lines 801J. Here the series 801 is next to the back electrode isolation line 820 and preferably is located under the front electrode isolation line separating adjacent cells. The series of shunt isolation lines 801 are discontinuous and intermittently have sections where back electrode material has been removed. The invention contemplates that the spacing between shunt isolation lines in a series may vary. Also the length of each individual shunt isolation line may be the same or different. Assuming a series 801 of shunt isolation lines each line having the same or substantially the same length and height the amount of continuity may roughly be calculated as [(shunt isolation line area)/(total series 801 area, which includes the shunt isolation lines and the area between the shunt isolation lines)]×100 equals the percent continuity. It is preferred that there is about 50% to 99% (100% is a solid shunt isolation line), more preferably between about 85-95% and most preferably between about 90% continuity in this embodiment. In this invention the series 801 may comprise patterns as well as shunt isolations lines. Shunt isolation lines 801J and others of this invention may extend all the way to the edge of the device or terminate short of the edge. This is further illustrated with reference to FIG. 9.

FIG. 9 shows a cross section of a device 900 where isolation line 920 cuts through the back electrode layer and separates individual cell 925 and 935A. Shunt isolation line 901J cuts through the back electrode and may be, but not required to be, substantially parallel to the continuous isolation line 920 and is located underneath or substantially underneath front electrode isolation line 913. In one embodiment back electrode shunt isolation line 901J and front electrode isolation line 913 are the same width or substantially the same width. In another embodiment back electrode shunt isolation line 901J is wider than front electrode isolation line 913. In another embodiment back electrode shunt isolation line 901J, comprises two lines, set side by side with minimal spacing, such that the width of both back electrode shunt isolation lines combined is at least as wide as or wider than front electrode isolation line 913.

### EXAMPLE 6

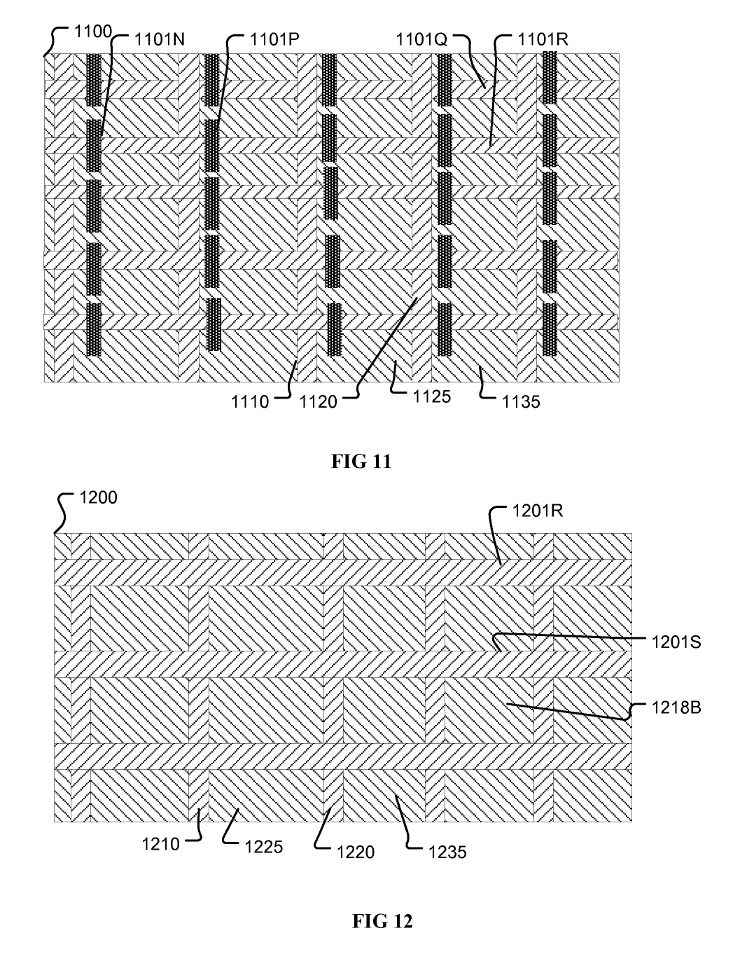

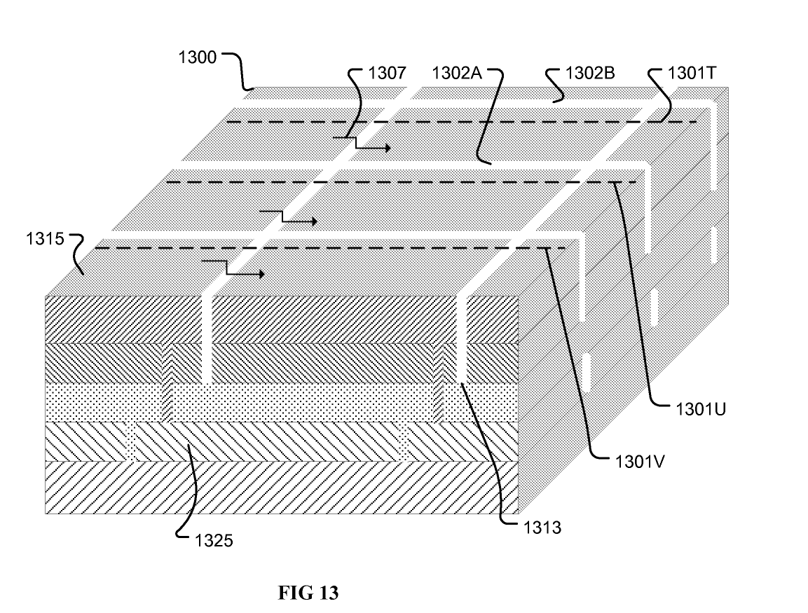

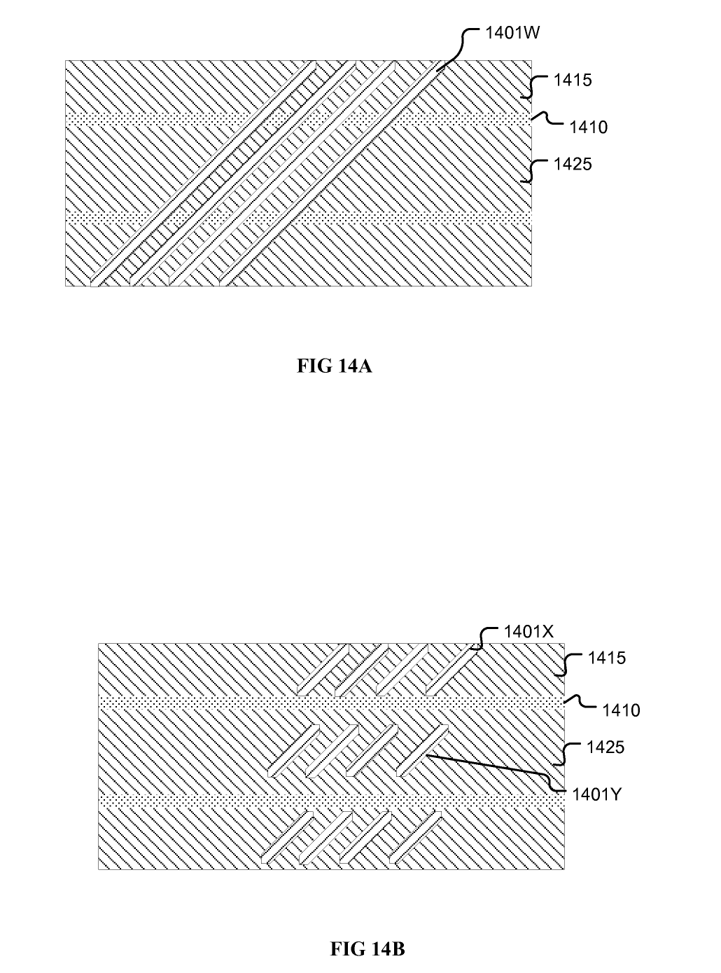

FIG. 10 shows a top view of a section of the back electrode layer of a device 1000 according to one embodiment of the present invention. Isolation lines 1010 and 1020 separate cells 1025 and 1035 through the back electrode layer. Shunt isolation scribes 1001K and 1001L are disposed next to the back electrode isolation line 1020. The shunt isolation lines 1001K and/or 1001L may extend all the way to the edge of the device or terminate short of the edge. The invention does not limit the number of patterns of shunt isolation lines that may used.

### EXAMPLE 7

FIG. 11 shows a top view of a section of the back electrode layer of a device 1100 according to one embodiment of the present invention. Back electrode isolation lines 1110 and 1120 cut fully through the back electrode layer and separate individual cells 1125 and 1135. Shunt isolation lines 1101Q and 1101R cut through the back electrode layer fully and extend substantially perpendicular to shunt isolation lines 1101N and 1101P dividing the cells in to sub-cell units. Shunt isolation line 1101P is disposed parallel to and near the isolation line 1110 and is repeated in a series extending across the cell. In this embodiment it can be seen that the shunt isolation line 1101N intersects the shunt isolation line 1101R. In another embodiment the shunt isolation line 1101N will not intersect the shunt isolation line 1101R. In another embodiment all of the shunt isolation lines in the series do not intersect any shunt isolation lines that extends perpendicular to the isolation lines that separate the cells. In this embodiment shunt isolation lines 1101P and 1101N are underneath or substantially underneath the front electrode isolation line (not shown) and may be the same width or substantially the same width as the front electrode isolation line. In another embodiment the shunt isolation line 1101P is wider the front electrode isolation line. In another embodiment shunt isolation line 1101P comprises two shunt isolation lines, such that the width of both lines combined is at least as wide as or wider than the front electrode isolation line.

### EXAMPLE 8

FIG. 12 shows an embodiment of the invention having a back electrode and a back side contact. This is disclosed in commonly assigned and copending U.S. Ser. No. 12/455,326, filed Jun. 1, 2009. Current flow is through vias 1281A and 1281B that extend through the substrate. FIG. 12 shows a top view of a section of the back electrode layer of a device 1200 according to one embodiment of the present invention. There is an isolation line 1210 and 1220 that separates cells 1225 and 1235. Shunt isolation lines 1201R and 1201S extend substantially perpendicular to the isolation lines and divides the cells into sub-cells. The invention contemplates that any of the shunt isolation lines described herein are suitable for use alone or in any combination of the back contact, the back electrode or the front electrode.

### EXAMPLE 9

FIG. 13 shows an example of a device 1300 having shunt isolation lines 1302A and 1302B in the front electrode layer. Shunt isolation lines 1302A and 1302B have 100 percent continuity because they extend from one edge of the cell to the other edge and extend perpendicular to the front electrode isolation line 1313. Arrow 1307 represents the direction of current flow through the device from the front electrode layer of cell 1315 to the back electrode layer of cell 1325. Shunt isolation lines 1301T, 1301U and 1301V are cut through the back electrode layer.

### EXAMPLE 10

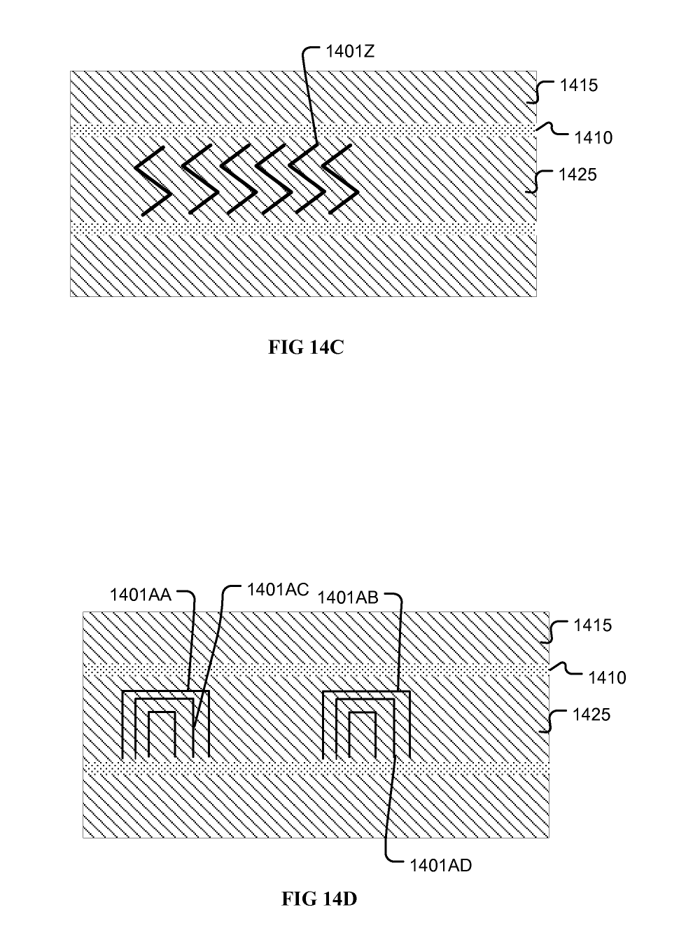

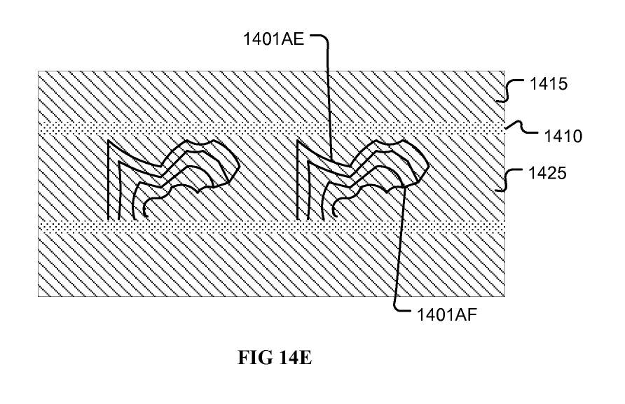

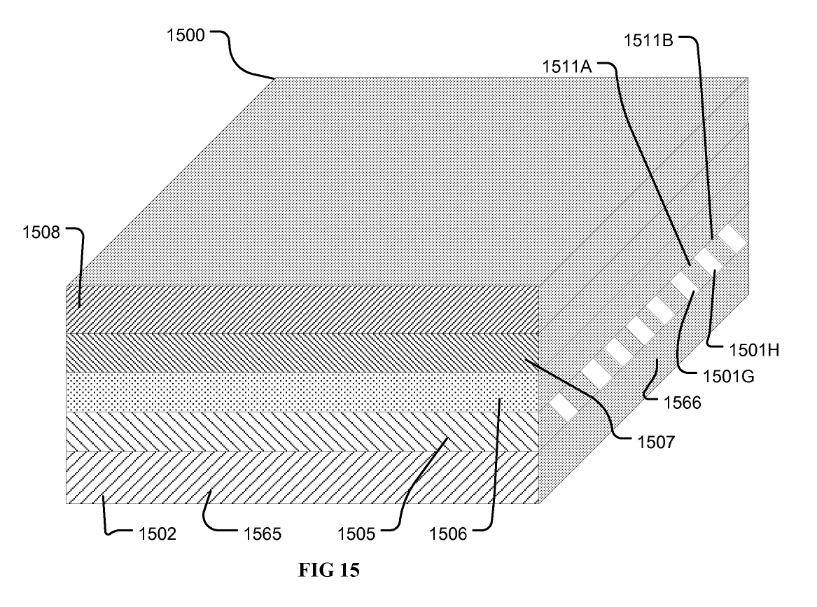

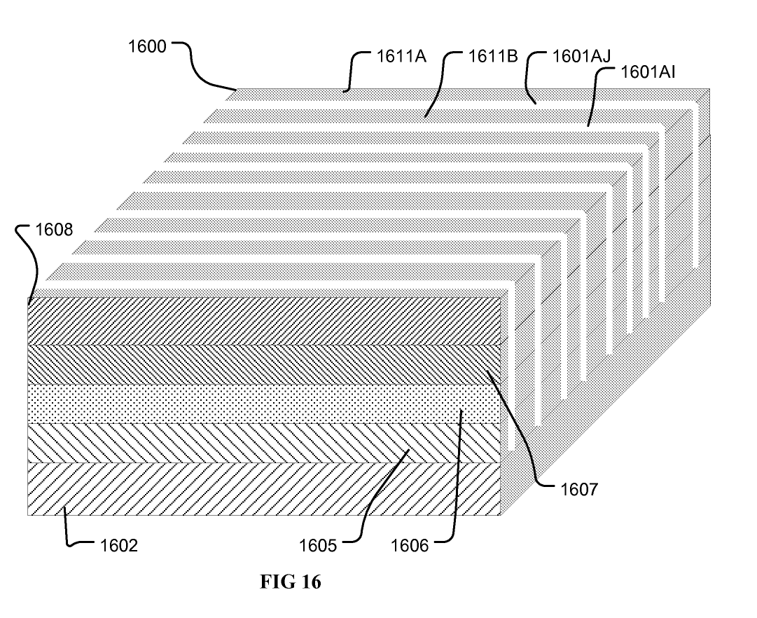

The invention contemplates that a wide variety of configurations of lines and patterns are possible for shunt isolation lines according to the present invention. FIGS. 14A-E provides illustrative but not exhaustive examples of these configurations. FIGS. 14A-E show partial top views of devices in accordance with embodiments of this invention. With reference to FIGS. 14A-14E cells 1415 and 1425 are separated by isolation line 1410. FIG. 14A illustrates shunt isolation lines 14701W that are non-orthogonal dividing individual cells into sub-cells. FIG. 14B illustrates shunt isolation lines 1401X and 1401Y that only partially divide cells. FIG. 14C illustrates shunt isolation lines 1401Z having turns. FIG. 14D illustrates shunt isolation lines 1401AA, 1401AB, 1401AC and 1401AD having turns. This embodiment shows that the spacing between shunt isolation lines 1401AA and 1401AC is different than the spacing between shunt isolation lines 1401AB and 1401AD. FIG. 14F shows complex shapes in shunt isolation lines 1401AE. In one embodiment shunt isolation line 1401AF connects to an end of shunt isolation line 1401AE.

### EXAMPLE 11

Shunt isolation lines in accordance with this invention are useful in discrete solar cells. In one embodiment of the present invention FIG. 15 shows discrete cell 1500 comprising a first edge 1565 and a second edge 1566 and a front electrode layer 1508, beneath that a window layer 1507, beneath that an absorber layer 1506, beneath that a back electrode layer 1505 resting on a substrate 1502. Shunt isolation lines 1501AG and 1501AH separate the cell into sub-cells 1511A and 1511B. Shunt isolation lines cut through the only the back electrode 1505. The invention contemplates that cell 1500 may also be part of a roll of cell material that may later be processed into a photovoltaic cell by adding appropriate leads and connections. Discrete cell 1500 may be connected in series with other cells as shown herein or may be subdivided into cells and they may be connected in series.

### EXAMPLE 12

FIG. 16 shows a discrete solar cell 1600 in accordance with another embodiment of the present invention having a front electrode layer 1608, beneath that a window layer 1607, beneath that an absorber layer 1606, beneath that a back electrode layer 1605 resting on a substrate 1602. Shunt isolation lines 160AI and 1601AJ separate the cell into sub-cells 1611A and 1611B. In this embodiment the shunt isolation lines cut through all layers except the substrate. The invention contemplates that cell 1600 may also be part of a roll of cell material that may later be processed into a photovoltaic cell by adding appropriate leads and connections. Cell 1600 may connected in series with other cells or may be divided into sections and they may be connected in series.

### EXAMPLE 13

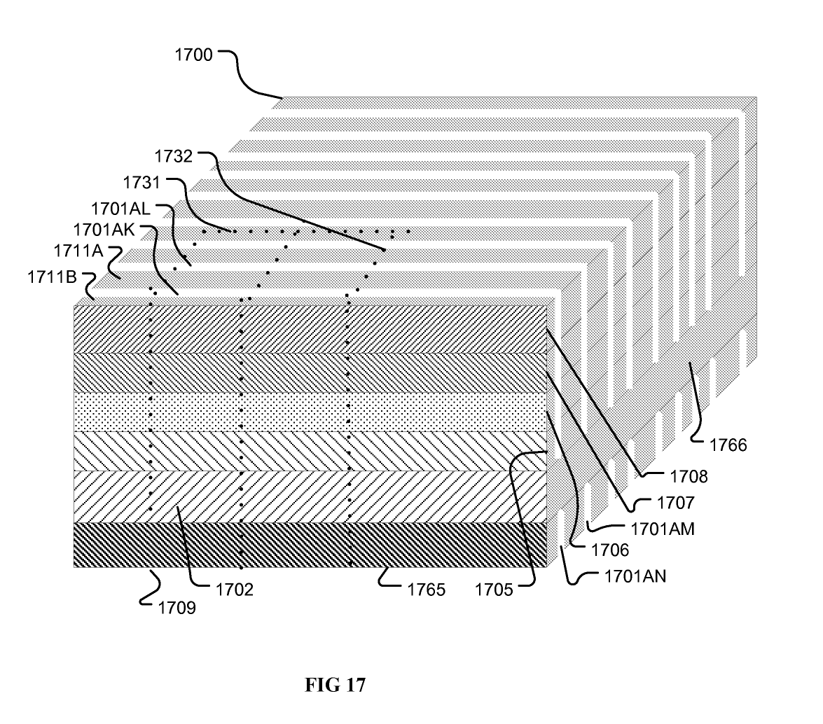

FIG. 17 shows a discrete cell 1700 in accordance with another embodiment of the invention comprising a first edge 1765 and second edge 1766 having a back contact 1709 and a back electrode 1705 on opposite sides of substrate 1702. Front electrode layer 1708 is on top of window layer 1707, beneath that an absorber layer 1706. In this embodiment shunt isolation lines 1701AM and 1701AN cut through the back contact 1709 cell and separate it into sub-cells 1711A and 1711B. (Note: in this embodiment there are vias (not shown) in the substrate and a “back contact” 1709 on one side of a substrate and a “back electrode” 1705 on the opposite side. Shunt isolation lines 1701AK and 1701AL cut through the front electrode layer 1708, the window layer 1707, the absorber layer 1706 and the back electrode 1705 to isolate the cell into sub-cells 1711A and 1711B. In this example vias (not shown) extend through the substrate as disclosed in commonly assigned and copending U.S. Ser. No. 12/455,326, filed Jun. 1, 2009. The invention contemplates that cell 1700 may also be part of a roll of cell material that may later be processed into a photovoltaic cell by additional processing and/or by adding appropriate leads and connections. The cell may be cut into any number of individual cells for series connection. Sections 1731 and 1732 may be cut from cell 1700 and joined to create a device. Alternatively, cell 1700 may be connected in electrical series with another similar.

### EXAMPLE 14

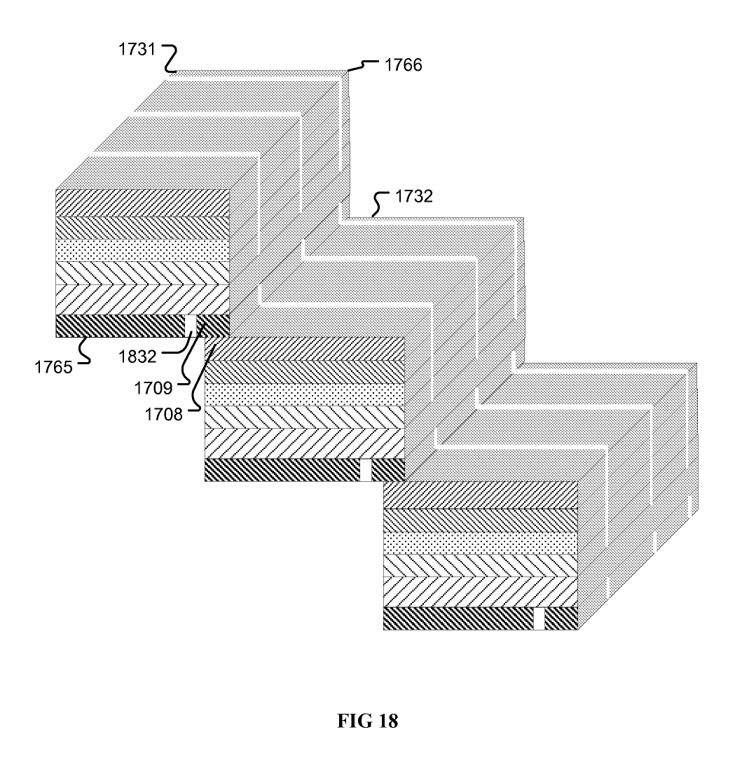

FIG. 18 shows an embodiment of the invention comprising cell 1730 having a first edge 1765 and second edge 1766 of Example 13 cut into sections which may be connected in electrical series. Discrete cells 1731 and 1732 are electrically connected by overlapping the back contact 1709 of discrete cell 1731 with the front electrode 1708 of cell 1732. Back contact isolation line 1832 cuts through the back contact to separate the positive and negative backside electrodes.

### EXAMPLE 15

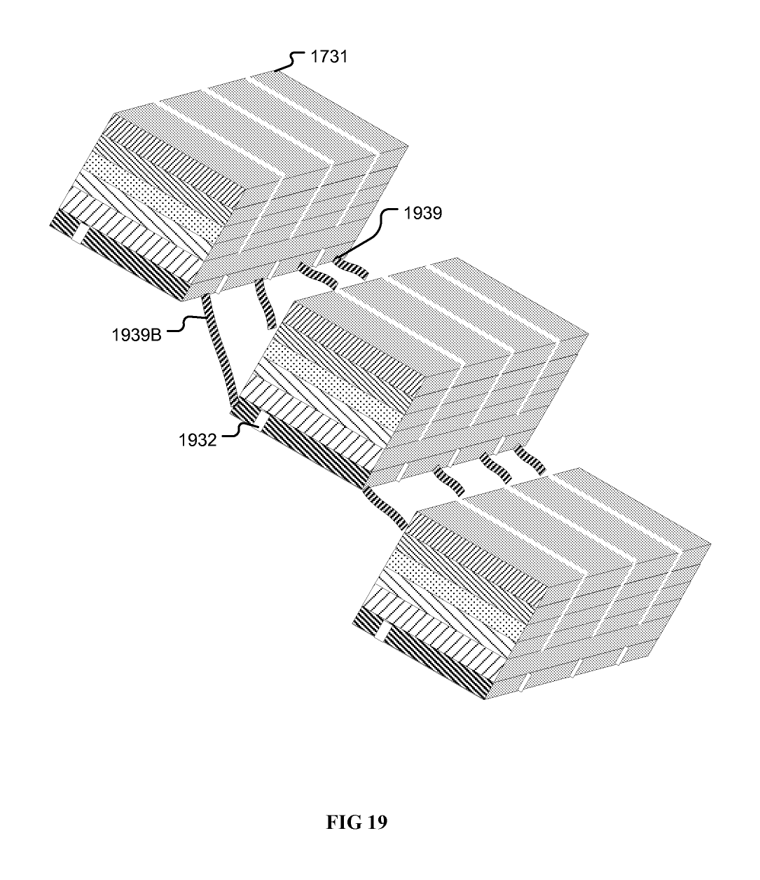

The discrete cell 1730 of Example 13 may be cut into any amount of individual discrete cells that may be connected in electrical series as shown in FIG. 19. Discrete cells 1731 and 1732 are connected by interconnects 1939 and 1939B. Each interconnect contacts the positive back contact of one cell and the negative back contact of the adjacent cell. Back contact isolation line 1932 cuts through the back contact to separate the positive and negative backside electrodes.

### EXAMPLE 16

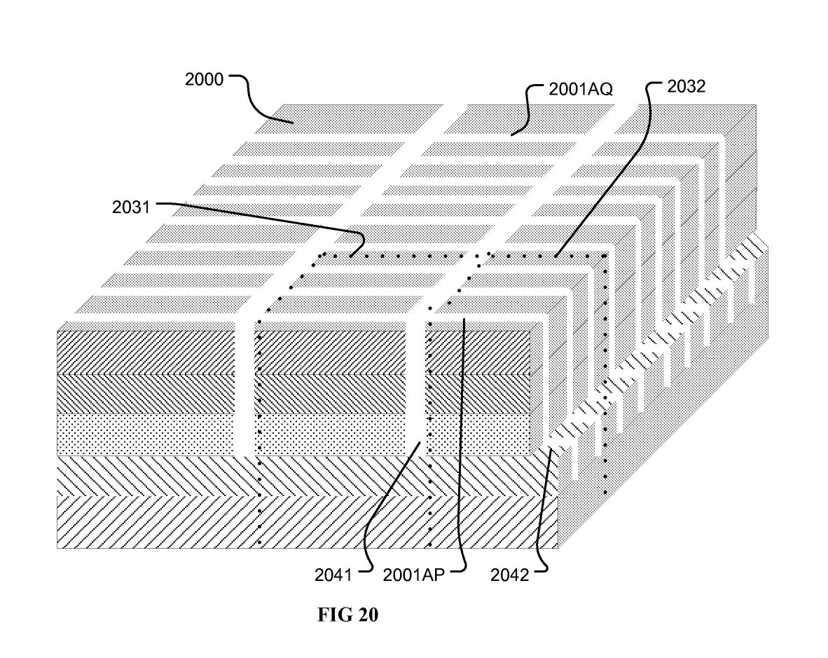

FIG. 20 shows an embodiment of the invention shown in Example 12 after further processing. Discrete cell 2000 has been divided by wide isolation lines 2041 and 2042 perpendicular to shunt isolation lines 2001AP and 2001AQ. Sections 2041 and 2042 of the front electrode layer, window layer and absorber layer have been completely removed to expose the back electrode layer. This embodiment is suitable for roll to roll processing and/or further processing. Sections 2031 and 2032 may be cut away completely from cell 2000 to from discrete cells and connected in electrical series.

### EXAMPLE 17

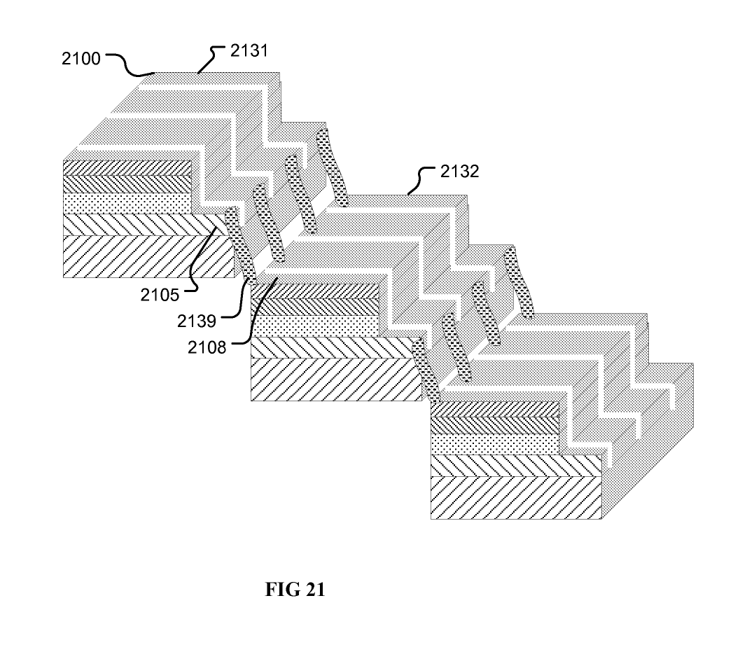

FIG. 21 show discrete cells 2031 and 2032 of Example 16 which have been cut from cell 2000 and connected in electrical series. Device 2100 may have as many discrete cells connected in series as desired. The connection is through conductive interconnect 2139 which connects the back electrode of cell 2131 to the front electrode 2108 of the adjacent cell.

### EXAMPLE 18

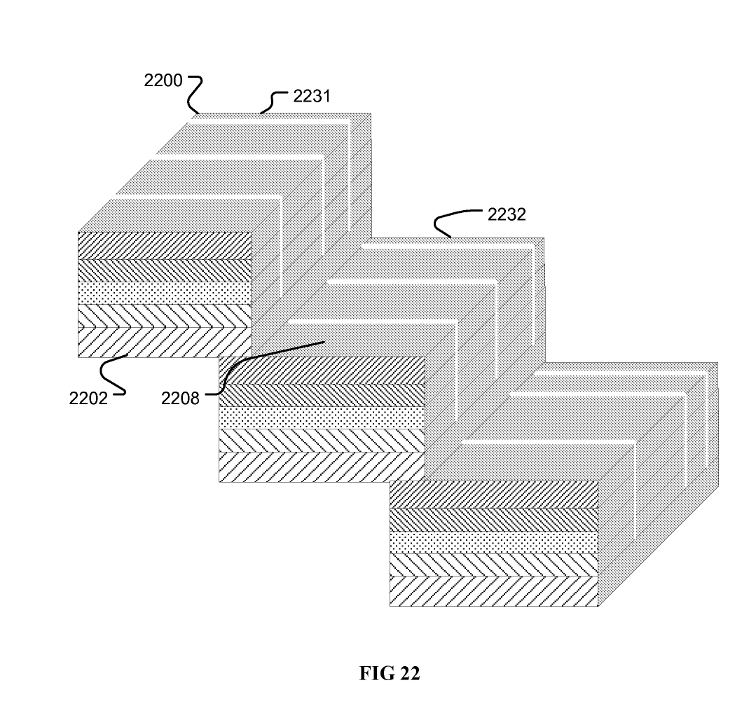

FIG. 22 shows device 2200 in accordance with another embodiment of the invention which may be made by connecting in electrical series multiple discrete cells similar to those shown in FIG. 16. Substrate 2202 is conductive and may be made of metal or other conductive material. The back electrode conducts electricity through the conductive substrate 2202. The discrete cell of Example 12 may be connected in series or it may be subdivided into smaller cells 2231 and 2232 and connected by overlapping the substrate 2202 with the front electrode 2208 of an adjacent cell.

It is understood that the embodiments described herein including the figures disclose only illustrative but not exhaustive examples of the layered structures possible by the present invention. All patents, publications and disclosures disclosed herein are hereby incorporated by reference in their entirety for all purposes. Unless so indicated by restricting and/or limiting language additional layers and/or parts of the photovoltaic device have been omitted for clarity.

What is claimed is:

1. A photovoltaic device, comprising:
a plurality of cells, wherein each cell comprises a front electrode and/or a back electrode, and
at least two cells are separated by a back electrode isolation line and a front electrode isolation line, wherein:
at least one cell further comprises:
a first shunt isolation line, wherein:
said first shunt isolation line is in the back electrode and/or the front electrode.

2. A photovoltaic device as claimed in claim 1, wherein:
said first shunt isolation line is substantially perpendicular to said back electrode isolation line.

3. A photovoltaic device as claimed in claim 2, wherein:
the first shunt isolation line divides at least two cells partially or wholly.

4. A photovoltaic device as claimed in claim 3, wherein:
said first shunt isolation line comprises a series of shunt isolation lines.

5. A photovoltaic device as claimed in claim 3, further comprising:
a second shunt isolation line, wherein:
said second shunt isolation line is substantially perpendicular to said first shunt isolation line.

6. A photovoltaic device as claimed in claim 1, wherein:
said first shunt isolation line is substantially non-orthogonal to said back electrode isolation line.

7. A photovoltaic device as claimed in claim 1, wherein:
said first shunt isolation line is substantially parallel to said back electrode isolation line.

8. A photovoltaic device as claimed in claim 7, wherein:
said first shunt isolation line is located underneath said front electrode isolation line.

9. A photovoltaic device as claimed in claim 8, wherein:
said first shunt isolation line comprises a series of first shunt isolation lines.

10. A photovoltaic device as claimed in claim 8, further comprising:
a second shunt isolation line located in the back electrode.

11. A photovoltaic device as claimed in claim 10, wherein:
said first shunt isolation line is substantially parallel to said second shunt isolation line.

12. A photovoltaic device, comprising:
a plurality of discrete cells connected in electrical series, wherein:
each cell comprises a front electrode and a back electrode, and
at least one discrete cell comprises a first shunt isolation line, wherein:
said first shunt isolation line is in the back electrode and/or the front electrode.

13. A photovoltaic device as claimed in claim 12, wherein:
each cell comprises a first edge, wherein:
said first shunt isolation line is substantially parallel to said first edge.

14. A photovoltaic device as claimed in claim 12, wherein:
wherein the first shunt isolation line divides a cell partially or wholly.

15. A photovoltaic device as claimed in claim 13, wherein:
said first shunt isolation line is in the back electrode.

16. A photovoltaic device as claimed in claim 13, wherein:
said first shunt isolation line comprises a series of shunt isolation lines.

17. A photovoltaic device as claimed in claim 12, further comprising:
a second shunt isolation line.

18. A photovoltaic device as claimed in claim 12, further comprising:
a second shunt isolation line, wherein:
said first shunt isolation line is substantially parallel to said second shunt isolation line.

19. A photovoltaic device as claimed in claim 12, wherein:
each cell comprises a first edge, and
said first shunt isolation line is substantially non-orthogonal to said first edge.

20. A photovoltaic cell, comprising:
a substrate, a back electrode, an absorber layer, and a front electrode,
and at least one cell comprises a shunt isolation line, wherein:
said shunt isolation line is in the back electrode and/or the front electrode.
